(19) United States
(12) Patent Application Publication
(10) Pub. No.: US 2015/0375864 A1
(43) Pub. Date: Dec. 31, 2015

(54) DISPLAY DEVICE FOR USE IN TRANSPORTATION EQUIPMENT

(71) Applicant: Panasonic Intellectual Property Management Co., Ltd., Osaka (JP)

(72) Inventor: Yoshihiko NAKANO, Osaka (JP)

(21) Appl. No.: 14/742,734

(22) Filed: Jun. 18, 2015

(30) Foreign Application Priority Data
Jun. 25, 2014 (JP) 2014-130003
Dec. 11, 2014 (JP) 2014-250954

(51) Int. Cl. B64D 11/00; H05K 5/00

(52) U.S. Cl. CPC B64D 11/00151; H05K 5/0017

(57) ABSTRACT

A display device for use in transportation equipment according to the present disclosure includes a monitor, a hold portion, a shaft portion, a regulation portion, and a release unit. The monitor is disposed on a back side of a seat, and configured to be switchable between a stowed state where a longitudinal direction is defined in a vertical orientation, and a deployed state where the longitudinal direction is defined in a horizontal orientation. The hold portion is disposed on a back side of the monitor, and supports a back of the monitor. The shaft portion is disposed on the back side of the monitor, and supports the hold portion such that the hold portion is rotatable together with the monitor. The regulation portion regulates rotation of the monitor in the stowed state. The release unit releases hold caused by the regulation portion such that the monitor is rotatable about the shaft portion when the monitor shifts from the stowed state to the deployed state.

### BACKGROUND

1. Field

The present disclosure relates to a display device for use in transportation equipment, and more particularly to a display device included in a seat back of an airplane or other equipment.

2. Description of the Related Art

In recent years, there has been provided a monitoring device within a cabin of transportation equipment, such as an airplane, a train, a bus, and a passenger boat. This monitoring device offers images or other display services for passengers (refer to Unexamined Japanese Patent Publication No. 2009-253943, for example).

As illustrated in FIG. 1, monitoring device 201 provided on an airplane or the like is disposed inside seat back 200a. In this case, monitoring device 201 in a screen size larger than a width of seat 200 is difficult to be equipped. Accordingly, conventional monitoring device 201 includes a liquid crystal panel or the like which meets installation restrictions of seat 200, such as the width of seat 200.

Under these circumstances, the conventional monitoring device is only allowed to include a monitor which meets a width restriction of a monitor attachment portion formed inside a seat width, and therefore is difficult to satisfy a recent demand for screen size enlargement.

The present disclosure provides a monitoring device which allows attachment of a monitor having a width larger than an attachment width and expandable up to a seat width under a width restriction of an attachment portion.

### SUMMARY

A display device for use in transportation equipment according to the present disclosure includes a monitor, a hold portion, a shaft portion, a regulation portion, and a release unit. The monitor is disposed on a back side of a seat, and configured to be switchable between a stowed state where a longitudinal direction is defined in a vertical orientation, and a deployed state where the longitudinal direction is defined in a horizontal orientation. The hold portion is disposed on a back side of the monitor, and supports a back of the monitor. The shaft portion is disposed on the back side of the monitor, and supports the hold portion such that the hold portion is rotatable together with the monitor. The regulation portion regulates rotation of the monitor in the stowed state. The release unit releases the hold caused by the regulation portion such that the monitor is rotatable about the shaft portion when the monitor shifts from the stowed state to the deployed state.

### BRIEF DESCRIPTION OF DRAWINGS

FIG. 1 is a perspective view illustrating a conventional monitoring device;

FIG. 2 is a perspective view illustrating a display device for use in transportation equipment according to an exemplary embodiment, showing a state where a monitor is stowed in a seat back;

FIG. 3 is a perspective view illustrating the display device for use in the transportation equipment according to the exemplary embodiment, showing a deployed state where the monitor is rotated 90 degrees from the stowed state;

FIG. 4 is a schematic view illustrating a configuration of a main part of a monitoring device in the state shown in FIG. 2;

FIG. 5 is a schematic view illustrating the configuration of the main part of the device in the state shown in FIG. 2;

FIG. 6 is a schematic view illustrating the configuration of the main part of the device in the state shown in FIG. 2;

FIG. 7 is a schematic view illustrating the configuration of the main part of the device in the state shown in FIG. 2;

FIG. 8 is a schematic view illustrating a configuration of a main part of the device in the state shown in FIG. 3;

FIG. 9 is a schematic view illustrating the configuration of the main part of the device in the state shown in FIG. 3;

FIG. 10 is a schematic view illustrating the configuration of the main part of the device in the state shown in FIG. 3; and

FIG. 11 is a block diagram illustrating an example of a control section of the device shown in FIG. 2.

### DETAILED DESCRIPTION OF THE PREFERRED EMBODIMENTS

A monitoring device equipped on an airplane is hereinafter described in detail with reference to the drawings as necessary, by way of example of a display device for use in transportation equipment according to the present disclosure. In the following description, excessively detailed explanation may be omitted depending on cases. For example, detailed explanation of well-known matters, or repeated explanation of substantially identical configurations may be omitted depending on cases. These omissions are made to avoid unnecessary redundancy of the following description, and help those skilled in the art easily understand the present disclosure.

The present inventors present the accompanying drawings and the following description only for the purpose of helping those skilled in the art fully understand the present disclosure, and therefore do not intend that the subject matters as claimed in the appended claims be limited to these drawing and description.

Similar reference marks, symbols, and numerals in the following description indicate similar constituent elements unless particularly specified otherwise. Constituent elements not essential to the present disclosure are not shown in the drawings, unless otherwise particularly specified.

Described hereinafter by way of example is a monitoring device provided on an airplane according to an exemplary embodiment of the present disclosure.

### 1. Configuration

### 1-1. Outline of Monitoring Device 100

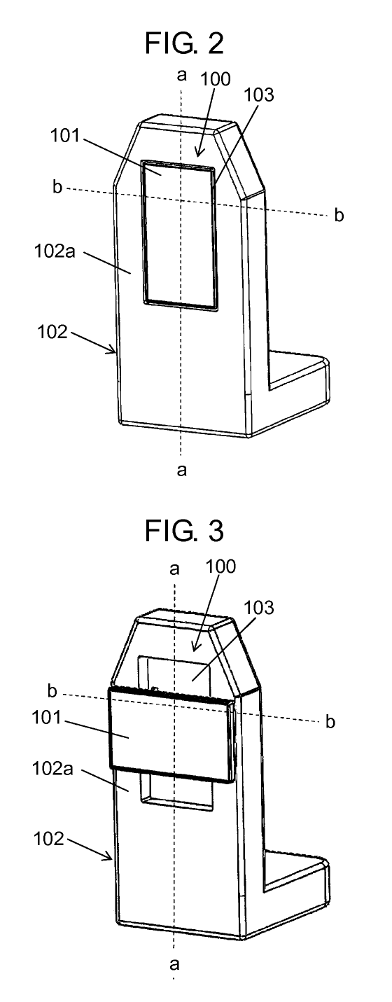

FIG. 2 is a perspective view illustrating the monitoring device according to this exemplary embodiment, showing a state where a monitor is stowed in a seat back. As illustrated in FIG. 2, monitor 101 of monitoring device 100 is stowed in monitor stowing recess 103 formed in back 102a of seat 102.

FIG. 3 is a perspective view illustrating the monitoring device according to this exemplary embodiment, showing a deployed state of the monitor rotated 90 degrees from the stowed state. As illustrated in FIG. 3, monitor 101 of monitoring device 100 is brought into a state held on back 102a of seat 102 when pulled out from monitor stowing recess 103 and rotated 90 degrees.

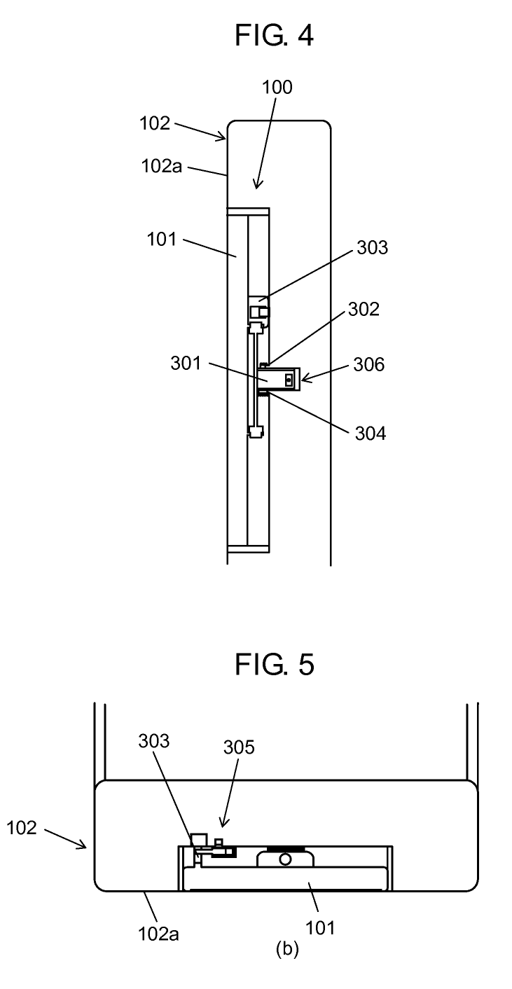

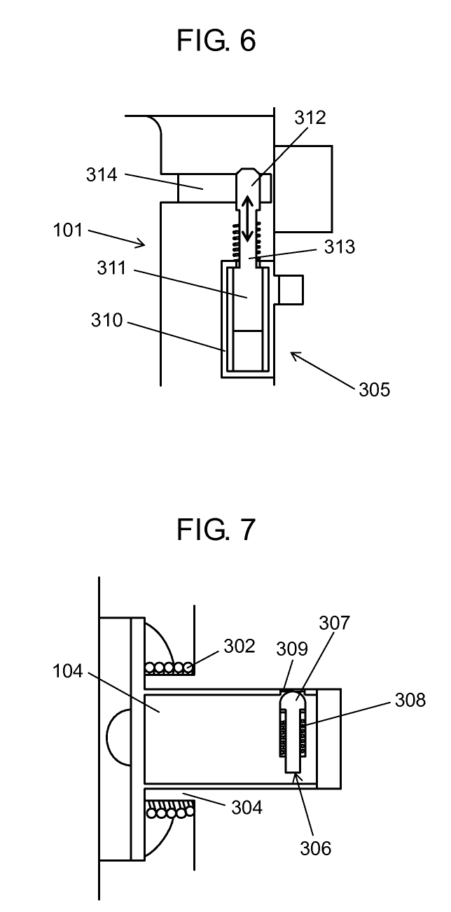

FIGS. 4, 5, 6, and 7 are schematic views illustrating a configuration of a main part of the monitoring device in the state shown in FIG. 2. FIG. 4 is a schematic view illustrating a cross-sectional structure taken along line a-a in FIG. 2. FIG. 5 is a schematic view illustrating a cross-sectional structure taken along line b-b in FIG. 2. FIG. 6 is an enlarged view illustrating release unit 305 and surroundings of release unit 305 in FIG. 5. FIG. 7 is an enlarged view illustrating regulation portion 306 and surroundings of regulation portion 306 in FIG. 4.

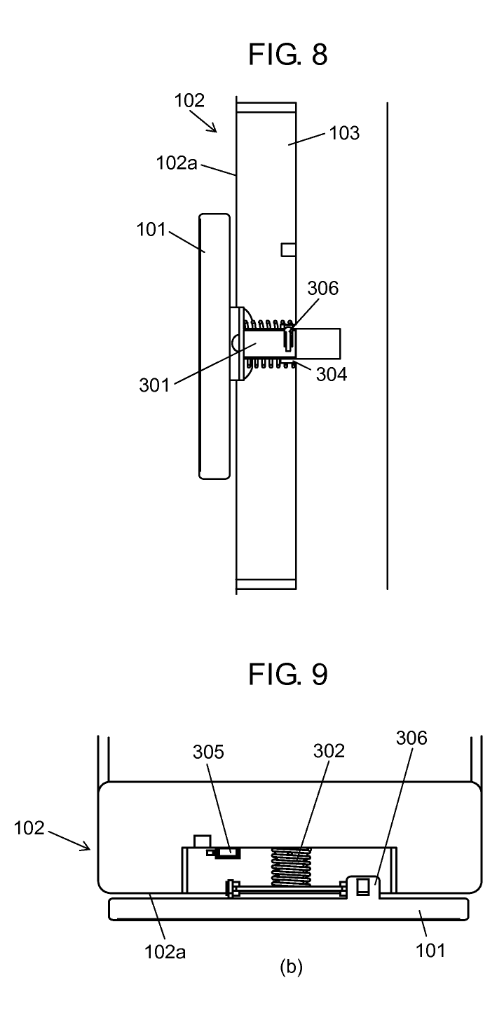

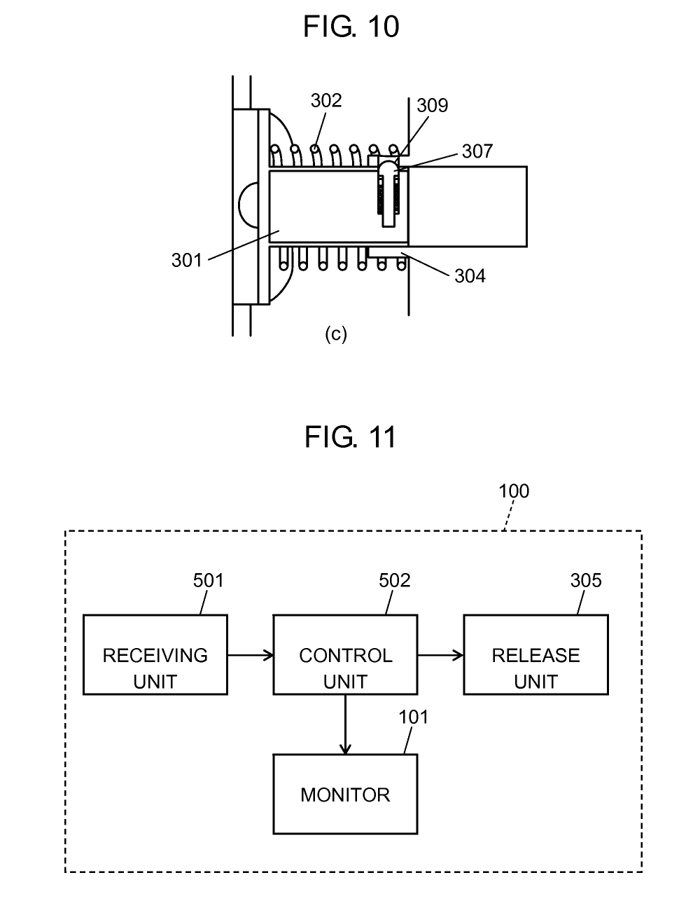

FIGS. 8, 9, and 10 are schematic views illustrating a configuration of a main part of the monitoring device in the state shown in FIG. 3. FIG. 8 is a schematic view illustrating a cross-sectional structure taken along line a-a in FIG. 3. FIG. 9 is a schematic view illustrating a cross-sectional structure of monitoring device 100 taken along line b-b in FIG. 3. FIG. 10 is an enlarged view illustrating regulation portion 306 and surroundings of regulation portion 306 in FIG. 8.

As illustrated in FIGS. 2 through 10, monitoring device 100 according to this exemplary embodiment includes monitor 101 disposed on a back 102a side of seat 102, and configured to be switchable between an stowed state where a longitudinal direction is defined in a vertical orientation, and a deployed state where the longitudinal direction is defined in a horizontal orientation.

Monitoring device 100 includes hold portion 301 which supports the back of monitor 101, shaft portion 304 disposed on the back side of monitor 101 and supporting hold portion 301 such that hold portion 301 is rotatable together with monitor 101, regulation portion 306 which regulates rotation of monitor 101 in the stowed state, and release unit 305 which releases regulation by regulation portion 306 and allows rotation of monitor 101 around shaft portion 304 at the time of state switching of monitor 101 from the stowed state to the deployed state.

Release unit 305 further includes locking portion 303 which regulates rotation of monitor 101, and locks monitor 101 at a predetermined position on back 102a side of seat 102. Spring portion 302 performs a function of pushing monitor 101 frontward when a locking state produced by locking portion 303 is released. According to this structure, monitor 101 is shifted to a projected state from back 102a of seat 102 by a pressing force of spring portion 302 when the hold by regulation portion 306 is released by release unit 305.

Monitor 101 is a display panel constituted by an LCD (Liquid Crystal Display), for example, and displays various types of information.

Hold portion 301 is a cylindrical member fixed to the back side of monitor 101. A first end of hold portion 301 is fixed to the back of monitor 101 in a direction perpendicular or substantially perpendicular to the back of monitor 101. Hold portion 301 is held in such a manner that the first end of hold portion 301 is rotatable on shaft portion 304 provided on the back of monitor 101. Hold portion 301 further includes regulation portion 306 at a second end of hold portion 301 on the side opposite to the first end fixed to the back of monitor 101. As illustrated in FIG. 7, regulation portion 306 includes fixing pin 307 and regulation spring member 308. Fixing pin 307 is urged by an elastic force of regulation spring member 308 to constantly apply a pressing force to shaft portion 304 along an axis of hold portion 301.

As illustrated in FIGS. 7 and 10, shaft portion 304 includes a locking hole 309 to which fixing pin 307 is fitted. Fixing pin 307 includes a sloped tip, and has a radius smaller than a radius of locking hole 309. According to this structure, monitor 101 is fixed not to freely rotate in a state that fixing pin 307 is fitted to locking hole 309.

When monitor 101 is rotated by a stronger force, free rotation of monitor 101 is allowed with release of locking between fixing pin 307 and locking hole 309.

As illustrated in FIGS. 4 and 5, monitor 101 is fixed in a state stowed within monitor stowing recess 103 formed in the back of seat 102. On the other hand, in a deployed state illustrated FIGS. 8 and 9, monitor 101 is pulled out from monitor stowing recess 103 and rotated 90 degrees.

Locking portion 303 is a member which locks monitor 101 at a predetermined position on back 102a of seat 102, i.e., within monitor stowing recess 103, and is disposed on the back side of monitor 101. Locking portion 303 is fixed to release unit 305. This structure allows accommodation of monitor 101 within monitor stowing recess 103 of seat 102.

As illustrated in FIG. 5, release unit 305 is disposed at a position facing to locking portion 303 in the state that monitor 101 is stowed within monitor stowing recess 103. As illustrated in FIG. 6, release unit 305 includes solenoid 310, iron core 311, pin 312, and release spring member 313.

Solenoid 310 is not energized in a normal condition, and switched to an energized state when receiving an electric signal from control unit 502. In a not-energized state of solenoid 310, iron core 311 is pushed out by a coil (not-shown) in accordance with an elastic force of release spring member 313. As a result, pin 312 is pushed out. Pin 312 thus pushed out is fitted to hole 314 of locking portion 303.

According to this exemplary embodiment, monitor 101 is fixed within monitor stowing recess 103 by this configuration of release unit 305 when solenoid 310 is not energized. When solenoid 310 is energized, iron core 311 is drawn by an electromagnetic force of the coil (not shown). As a result, pin 312 connecting with iron core 311 shifts in such a direction as to withdraw from a position within hole 314.

Accordingly, locking of monitor 101 is released by energization of solenoid 310.

Spring portion 302 is provided on the back side of monitor 101 to apply an urging force in a direction perpendicular to monitor 101. According to this structure, monitor 101 comes into a state allowed to be pulled out from monitor stowing recess 103 after release of locking of monitor 101 by energization of solenoid 310 under control of control unit 502.

FIG. 11 is a block diagram illustrating an example of a control section of the monitoring device shown in FIG. 2.

As illustrated in FIG. 11, receiving unit 501 receives information from an external control system, such as a core system of an airplane. Control unit 502 determines whether to transmit an electric signal to release unit 305 based on the information received by receiving unit 501, and transmits an electric signal to release unit 305 in accordance with this determination. In addition, control unit 502 displays, on monitor 101, a display screen (such as a menu) to be presented to a passenger, and receives a user instruction issued by operation of the display screen on monitor 101.

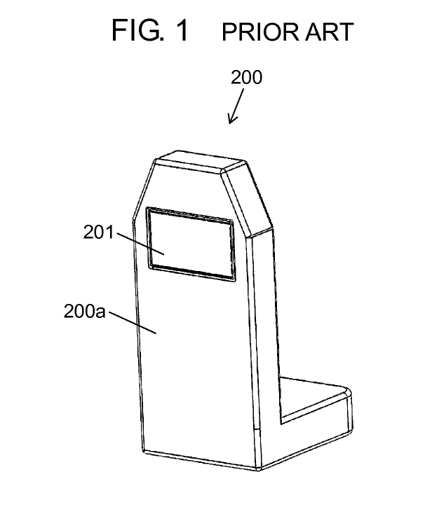

Monitoring device 100 constructed as above according to this exemplary embodiment is switchable between two states, i.e., the stowed state (FIG. 1) where monitor 101 is stowed in monitor stowing recess 103 of seat 102 such that a surface of monitor 101 forms a plane leveled with the back of seat 102, and the deployed state (FIG. 3) where monitor 101 is pulled out from seat 102 and rotated 90 degrees.

### 2. Operation

### 2-1. Operation of Monitoring Device 100 in Stowed State

Discussed herein is an example of operation of monitoring device 100 when an instruction for fastening a seat belt is issued before a takeoff or in an airframe ascending state of the airplane.

For starting a flight of the airplane, a pilot initiates actuation of the airframe, including energization of monitoring device 100. A passenger is required to fasten a seat belt before a takeoff or in an airframe ascending state, and receives issue of a seat belt fastening instruction.

In this condition, receiving unit 501 receives no information. Accordingly, control unit 502 does not transmit an electric signal to solenoid 310.

Solenoid 310 thus is in a not-energized state in this condition. Therefore, pin 312 is in the state fitted to locking portion 303. In this situation, monitor 101 is stowed in monitor stowing recess 103, and not allowed to be shifted or rotated to switch from the stowed state to the deployed state.

As described above, monitoring device 100 is in the state stowed within monitor stowing recess 103 when a seat belt release instruction is not issued before a takeoff or in an airframe ascending state. Accordingly, rotation of monitor 101 is regulated in this condition.

### 2-2. Operation of Monitoring Device 100 in Normal State

Discussed next is operation of monitoring device 100 when a seat belt release instruction is issued in a stable flight state of the airplane.

After the airframe is shifted to the stable flight state, the seat belt release instruction is automatically issued from the external core system. At this time, receiving unit 501 of monitoring device 100 receives the seat belt release instruction from the external system (such as core system).

Control unit 502 receives the seat belt release instruction from receiving unit 501, and transmits an electric signal to solenoid 310.

As a result, solenoid 310 comes into the energized state, whereby iron core 311 is drawn by a magnetic force. Consequently, pin 312 is separated from locking portion 303, releasing fixation of monitor 101.

Monitor 101 thus shifts to a state of cancellation of the fitting condition between locking portion 303 and release unit 305. Monitor 101 in this condition projects from seat 102 in accordance with pressing by spring portion 302. Monitor 101 is configured to be rotatable about shaft portion 304 in this condition. Accordingly, monitor 101 is allowed to rotate 90 degrees to shift from a vertically long position to a horizontally long position in accordance with manual operation by the passenger as illustrated in FIG. 3.

Image display on monitor 101 is allowed in the deployed state after 90-degree rotation. Accordingly, the passenger is allowed to view images or the like distributed within the cabin.

Monitor 101 in the stowed state is in the vertically long position, but shifts to the horizontal long position by 90-degree rotation. Accordingly, the passenger is allowed to view images or the like distributed within the cabin in a larger screen size than a conventional screen size.

In a conventional monitoring device, a monitor embedded in a seat is disposed in the horizontally long position. In this case, a screen size is limited to a size smaller than a width of the seat.

In monitoring device 100 in this exemplary embodiment, however, monitor 101 shifts to a position projecting from the back of seat 102 to come into a rotatable state, and then rotates 90 degrees in accordance with manual operation by the passenger. This structure allows enlargement of the screen size to a size closest to the seat width. Accordingly, the passenger is allowed to receive image distribution services in a larger screen size.

### 3. Advantageous Effects

As described above, the configuration of monitoring device 100 according to this exemplary embodiment achieves automatic switching of the position of monitor 101 from the vertically long stowed state to the horizontally long deployed state when a seat belt release instruction is received. The passenger therefore is allowed to switch the position of monitor 101 by manual operation in accordance with preference of the passenger. Accordingly, the screen size of monitoring device 100 is allowed to increase up to a size closest to the seat width.

Moreover, monitoring device 100 displays images in the vertically long state as well, even in the stowed state where the surface of monitoring device 100 forms a plane leveled with the back of seat 102. Accordingly, the passenger can view images of evacuation procedures for an emergency, and common distribution of images within the cabin, in a manner producing no inferiority to the conventional monitoring device.

When not desiring the deployed state with 90-degree rotation after projection of monitoring device 100 from the back of seat 102, the passenger may continue viewing images on monitoring device 100 in the stowed state during stable flight.

### Other Exemplary Embodiments

The present disclosure is not limited to the exemplary embodiment of the present disclosure described herein. It is intended that various modifications be made without departing from the scope of the present disclosure.

### A

According to this exemplary embodiment described as an example herein, a seat belt release instruction is received from the external core system. However, the present disclosure is not limited to this example.

For example, control unit 502 may determine whether to release the seat belt based on received data about an altitude or vibration of the airplane measured by the external core system.

### B

According to this exemplary embodiment described as an example herein, whether to release the seat belt is determined based on the seat belt release instruction received from the external core system. However, the present disclosure is not limited to this example.

For example, the passenger may allow energization of solenoid 310 by using a menu display shown on monitor 101 so as to rotate monitor 101 even when the seat belt release instruction is not received from the external core system.

### C

According to this exemplary embodiment described as an example herein, solenoid 310 is provided as an element of release unit 305. However, the present disclosure is not limited to this example.

For example, revolutions of a motor may be utilized as an element of the release unit for shifting pin 312, in place of the use of solenoid 310.

### D

According to this exemplary embodiment described as an example herein, the monitoring device according to the present disclosure is applied to a seat monitor provided on the back of the seat equipped within the cabin of the airplane. However, the present disclosure is not limited to this example.

For example, the monitoring device according to the present disclosure is applicable to a monitoring device equipped on a train, a bus, a vessel or other moving bodies, or other places such as a hall equipped with seat monitors, as well as the airplane.

A monitoring device according to the present disclosure offers an advantage of realizing attachment of a monitor having a width larger than a width of an attachment portion under a restricted condition of the width of the attachment portion. Accordingly, the monitoring device according to this disclosure is applicable to a wide variety of monitor stowing devices provided on a seat back.

What is claimed is:

1. A display device for use in transportation equipment, the display device comprising:
a monitor disposed on a back side of a seat, and configured to be switchable between a stowed state where a longitudinal direction is defined in a vertical orientation, and a deployed state where the longitudinal direction is defined in a horizontal orientation;
a hold portion disposed on a back side of the monitor and supporting a back of the monitor;
a shaft portion disposed on the back side of the monitor and supporting the hold portion such that the hold portion is rotatable together with the monitor;
a regulation portion that regulates rotation of the monitor in the stowed state; and
a release unit that releases hold caused by the regulation portion such that the monitor is rotatable about the shaft portion when the monitor shifts from the stowed state to the deployed state.

2. The display device for use in the transportation equipment according to claim 1, wherein
the release unit includes a locking portion that regulates the rotation of the monitor, and locks the monitor at a predetermined position on the back side of the seat, and
the display device further includes a spring portion that presses the monitor frontward when a locking state by the locking portion is released.

3. The display device for use in the transportation equipment according to claim 2, wherein the monitor shifts to a state projected from a back of the seat by a pressing force of the spring portion when the hold by the regulation portion is released by the release unit.

4. The display device for use in the transportation equipment according to claim 1, wherein the monitor is stowed in a recess formed on the back side of the seat in the stowed state.

5. The display device for use in the transportation equipment according to claim 4, wherein the monitor is disposed in such a condition that a surface of the monitor forms a plane leveled with the back of the seat in the stowed state where the monitor is stowed within the recess.

6. The display device for use in the transportation equipment according to claim 1, wherein the release unit releases the hold based on information received from an external device.

7. The display device for use in the transportation equipment according to claim 1, further comprising a control unit that gives the release unit an instruction whether or not the hold is released.
